(19) United States
(12) Patent Application Publication
(10) Pub. No.: US 2023/0412167 A1
(43) Pub. Date: Dec. 21, 2023

(54) Power Electronic Module Comprising a Gate-Source Control Unit

(71) Applicant: Danfoss Silicon Power GmbH, Flensburg (DE)

(72) Inventor: Tobias APPEL, Flensburg (DE)

(21) Appl. No.: 18/248,081

(22) PCT Filed: Oct. 8, 2021
(86) PCT No.: PCT/EP2021/077865

§ 371 Date: Apr. 6, 2023

(30) Foreign Application Priority Data
Oct. 8, 2020 (DE) 10 2020 126 465.8

(51) Int. Cl. H03K 17/16

(52) U.S. Cl. CPC H03K 17/162; H03K 17/168

(57) ABSTRACT

A power electronic module (2) includes at least one semiconductor switch (4) and a gate-source control unit. The gate-source control unit includes an asymmetric transient voltage suppressor (TVS) diode (8) or two Zener diodes (10, 10′) or one or more avalanche diodes arranged between the gate terminal (G) and the source terminal (S) of the semiconductor switch (4).

### CROSS-REFERENCE TO RELATED APPLICATIONS

This application is a National Stage application of International Patent Application No. PCT/EP2021/077865, filed on Oct. 8, 2021, which claims priority to German Patent Application No. 10 2020 126 465.8, filed on Oct. 8, 2020, each of which is hereby incorporated by reference in its entirety.

### TECHNICAL FIELD

The present invention relates to a gate driver for a power electronic module comprising at least one semiconductor switch.

### BACKGROUND

Semiconductor switches such as Silicon Carbide (SiC) Metal-Oxide-Semiconductor Field-Effect Transistors (MOSFETs) are widely used and they are becoming more and more popular because they offer the advantages of higher blocking voltage, lower on-state resistance, and higher thermal conductivity than traditional silicon MOSFETs. Accordingly, SiC MOSFETs can replace silicon MOSFETs and Insulated gate bipolar transistors (IGBTs) in many applications.

In order to be able to maintain a reliable operation of SiC MOSFETs, however, the gate-source voltage (V_{GS}) is e.g. not allowed to fall below −4V. Therefore, the static gate voltage has to be above −4V, however, this causes a parasitic, or unwanted, turn-on of the power MOSFET. The parasitic turn-on of the power MOSFET is a phenomenon which happens in the reality more often and can cause more damage than usually known. The parasitic turn-on of the power MOSFET maybe leads to the destruction or damage of the power MOSFET and often it is afterwards difficult and sometimes not possible to identify the true cause of the failure. Otherwise it causes more losses of energy then necessary.

Accordingly, it is desirable to provide a power electronic module that comprises an improved gate driver.

It is an object of the invention to provide a gate driver that is simple, fast and show a high current capability.

It is also an object of the invention to provide a gate driver that does not require additional terminals to be controlled.

### SUMMARY

The object of the present invention can be achieved by a power electronic module as defined in claim 1. Preferred embodiments are defined in the dependent subclaims, explained in the following description and illustrated in the accompanying drawings.

The power electronic module according to the invention is a power electronic module comprising at least one semiconductor switch and a gate-source control unit, wherein the gate-source control unit comprise an asymmetric transient voltage suppressor (TVS) diode or two Zener or one or more avalanche diodes arranged between the gate terminal and the source of the die or terminal of the semiconductor switch. Hereby, it is possible to provide an improved gate driver that is simple, fast and show a high current capability. Moreover, the gate driver does not require additional terminals to be controlled.

By the term “semiconductor switch” is meant an electronic switch formed as an electronic component configured to alternately let power flow and block power from flowing in a controlled manner.

The “semiconductor switch” may be a component in an integrated circuit shaped as a small block of semiconducting material constituting a die.

The term “arranged between the gate terminal and the source terminal of the die or of the semiconductor switch” includes “arranged between the gate terminal and the source terminal of the die” in case that the semiconductor switch is provide as a die.

The gate-source control unit is arranged internally in the power electronic module.

In one embodiment, the gate-source control unit is arranged internally in a power electronic module that comprises a circuit carrier substrate such as a Direct Copper Bond substrate (DCB-substrate), a Direct Aluminium Bond substrate (DAB-substrate), an Active Metal Braze substrate (AMB-substrate), a Printed Circuit Board substrate (PCB-substrate) or other known forms of circuit carrier substrate.

In one embodiment, the asymmetric TVS diode is placed on the circuit carrier substrate.

In one embodiment, the Zener diodes are placed on the circuit carrier substrate.

In one embodiment, the one or more avalanche diodes are placed on circuit carrier substrate.

It should be noted that an avalanche diode is commonly encountered as a high voltage Zener diode.

In one embodiment, the gate-source control unit is arranged internally in a power electronic module that comprises a circuit carrier substrate, wherein no additional electrical components other than the TVS diode or two Zener diodes or the one or more avalanche diodes are arranged between the gate terminal and the source terminal of the semiconductor switch.

The gate driver is a voltage-source placed next to the gate terminal of the semiconductor switch internally in the power electronic module. It is preferred that the distance between the gate terminal of the semiconductor switch and the gate driver is short.

In one embodiment, the distance between the gate terminal of the semiconductor switch and the gate driver is less than 10 mm.

In one embodiment, the distance between the gate terminal of the semiconductor switch and the gate driver is less than 8 mm.

In one embodiment, the distance between the gate terminal of the semiconductor switch and the gate driver is less than 6 mm.

In one embodiment, the distance between the gate terminal of the semiconductor switch and the gate driver is less than 4 mm.

In one embodiment, the distance between the gate terminal of the semiconductor switch and the gate driver is less than 2 mm.

In one embodiment, the distance between the gate terminal of the semiconductor switch and the gate driver is less than 1 mm.

In one embodiment, an asymmetric transient voltage suppressor diode TVS-Diode.

In one embodiment, two Zener diodes are arranged internally in the power electronic module in such a manner that the power electronic module is configured to drive each of the two Zener diodes with a static current.

The internal Zener diodes are oppositely connected and are capable of stabilizing the gate driver voltage of e.g. −7V to −4V. Accordingly, there is a current flow through the terminal and the terminal inductance which compensates the inductance.

In one embodiment, the semiconductor switch is a MOSFET. The use of a MOSFET is advantageous because it is a very compact transistor that has been miniaturised and mass-produced for a wide range of applications. A MOSFET requires almost no input current to control the load current, when compared with bipolar junction transistors (BJTs).

Moreover, a MOSFET also have faster switching speed, smaller size, consume less power, and enable higher density compared to BJTs. Besides MOSFETs are also cheaper.

In one embodiment, that the semiconductor switch is a junction gate field-effect transistor (JFET).

In one embodiment, the semiconductor switch is a bipolar transistor.

In one embodiment, the semiconductor switch is a SiC-based semiconductor switch.

In one embodiment, the semiconductor switch is a Gallium nitride (GaN)-based switch.

In one embodiment, the semiconductor switch is a is an Insulated gate bipolar transistor (IGBT).

In one embodiment, the semiconductor switch is a N-Channel Enhancement Mode MOSFET.

In a preferred embodiment, the semiconductor switch is a SiC MOSFET.

In one embodiment, the power electronic module comprises:
a first terminal electrically connected to the gate of the terminal semiconductor switch;
a second terminal electrically connected to the source terminal of the semiconductor switch and
a third terminal electrically connected to the drain terminal of the semiconductor switch,
   wherein no Zener diode is arranged between the source terminal and the drain terminal.

In one embodiment, the gate-source control unit comprise a first Zener diode that has a breakdown voltage in the range of 1.8-5.6 V and a second avalanche diode that has a breakdown voltage of 1.8-5.6 V.

In one embodiment, the gate-source control unit comprise a first avalanche diode that has a breakdown voltage in the range of 5-35 V and a second avalanche diode that has a breakdown voltage of 5-35 V.

In one embodiment, the gate-source control unit comprise a first avalanche diode that has a breakdown voltage in the range of 10-30 V and a second avalanche diode that has a breakdown voltage of 10-30 V.

In one embodiment, the gate-source control unit comprise a first avalanche diode that has a breakdown voltage in the range of 15-25 V and a second avalanche diode that has a breakdown voltage of 15-25 V.

In one embodiment, the gate-source control unit comprise a first avalanche diode that has a breakdown voltage in the range of 18-22 V and a second avalanche diode that has a breakdown voltage of 18-22 V.

In one embodiment, that the semiconductor switch is a MOSFET that has a maximum dynamic gate-source voltage range of −8V to 19V.

In one embodiment, that the semiconductor switch is a MOSFET that has a maximum dynamic gate-source voltage range of −4V to 15V.

In one embodiment, the power electronic module is configured to drive the asymmetric TVS Diode or the two Zener Diodes or the one or more avalanche diodes with a static current.

In one embodiment the gate-source control unit is arranged internally in the power electronic module and the power electronic module comprises a circuit carrier substrate.

By “internally” is meant that the gate-source control unit herein described is contained within the packaging that constitutes the power electronics module. Such packaging may take a number of forms well known within the field and dictated by the application environment of the power electronics module, or the specific requirements of manufacturing or use. One known packaging is that of a molded module, where the control and switching circuitry is totally encapsulated in an insulating mold material and conducting leads protrude from the mold material. Another known packaging is that of a frame module, where the substrate on which electronic components such as the semiconductor switch and/or the gate-source control unit, is surrounded by an open frame which is closed by a lid. A common characteristic of a packaging is that it protects the electronic components, such as the semiconductor switch and/or the gate-source control unit, and connection circuitry from environmental dust or humidity as well as protecting such components from shock loadings.

In one embodiment no additional electrical components other than the TVS diode or two Zener diodes or the one or more avalanche diodes are arranged between the gate terminal and the source terminal of the semiconductor switch.

It is preferred that the distance between the gate terminal of the semiconductor switch and the gate driver is short.

In one embodiment the gate-source control unit is mounted on the same substrate as the semiconductor switch.

Such a configuration may be an advantage since it allows the distance between the gate terminal of the semiconductor switch and the gate driver to be kept to a minimum.

In one embodiment the gate-source control unit is mounted a different substrate to the substrate on which the semiconductor switch is mounted.

Such a configuration be an advantage since it allows the distance between the gate terminal of the semiconductor switch and the gate driver to be kept to a minimum since one of the two substrates may be mounted directly above the other substrate.

### BRIEF DESCRIPTION OF THE DRAWINGS

The invention will become more fully understood from the detailed description given herein below. The accompanying drawings are given by way of illustration only, and thus, they are not limitative of the present invention. In the accompanying drawings:

FIG. 1 shows a circuit diagram of a first embodiment according to the invention;

FIG. 2 shows the recommended and maximum voltage for reliable operation of a SiC MOSFET;

FIG. 3A shows the current and voltage of the as function of time for a power electronic device according to the invention and a prior art power electronic device and, shows a graph depicting the current as function of time for a power electronic device according to the invention and a prior art power electronic device;

FIG. 3B shows the current and voltage of the as function of time for a power electronic device according to the invention and a prior art power electronic device and, shows a graph depicting the voltage as function of time for a power electronic device according to the invention and a prior art power electronic device;

FIG. 4 shows a circuit diagram of a second embodiment according to the invention according to the invention;

FIG. 5A shows a circuit diagram of one embodiment according to the invention; and

FIG. 5B shows another view of the same circuit diagram as shown in FIG. 5A.

### DETAILED DESCRIPTION

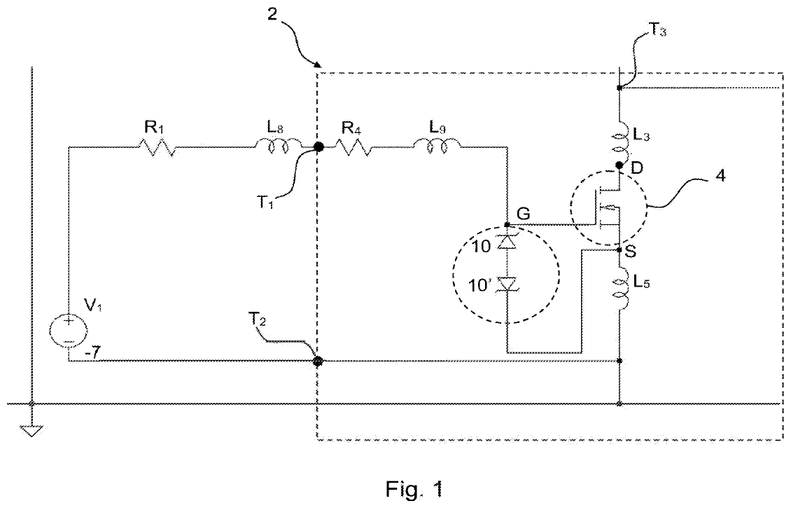

Referring now in detail to the drawings for the purpose of illustrating preferred embodiments of the present invention, a circuit diagram of a first embodiment according to the invention is illustrated in FIG. 1.

FIG. 1 illustrates a circuit diagram of a first embodiment of a power electronic module 2 according to the invention. The power electronic module 2 comprises a gate-source control unit (also referred to as a gate driver) arranged internally in a power electronic module 2. In a preferred embodiment, the power electronic module 2 comprises a circuit carrier substrate such as a Direct Copper Bond substrate (DCB-substrate), a Direct Aluminium Bond substrate (DAB-substrate), an Active Metal Braze substrate (AMB-substrate), a Printed Circuit Board substrate (PCB-substrate) or other known forms of circuit carrier substrate. A DC voltage source with potentials V₁ and −7V is indicated.

By “internally” is meant that the gate-source control unit herein described is contained within the packaging that constitutes the power electronics module 2. Such packaging may take a number of forms well known within the field and dictated by the application environment of the power electronics module, or the specific requirements of manufacturing or use. One known packaging is that of a molded module, where the control and switching circuitry is totally encapsulated in an insulating mold material and conducting leads protrude from the mold material. Another known packaging is that of a frame module, where the substrate on which electronic components such as the semiconductor switch 2 and/or the gate-source control unit is surrounded by an open frame which is closed by a lid. A common characteristic of a packaging is that it protects the electronic components, such as the semiconductor switch 2 and/or the gate-source control unit, and connection circuitry from environmental dust or humidity as well as protecting such components from shock loadings.

The power electronic module 2 comprises a first terminal T₁ and a second terminal T₂. The power electronic module 2 comprises a semiconductor switch shaped as a SiC MOSFET 4 having a gate terminal G, a source terminal S, and a drain terminal D. Two Zener diodes 10, 10′ are oppositely connected and arranged between the gate terminal G and the source terminal S of the SiC MOSFET 4. The two Zener diodes 10, 10′ are capable of stabilizing the gate driver voltage.

It can be seen that no additional electrical components other than the two Zener diodes 10, 10′ are arranged between the gate terminal G and the source terminal S of the SiC MOSFET 4. Moreover, the resistance and inductance are indicated by resistors R₁, R₄ and inductors L₃, L₅, L₈, L₉.

As previously explained, the SiC MOSFET 4 may be replaced by another type of semiconductor switch. The SiC MOSFET 4 may be replaced by another type of semiconductor switch such as one of the following: a MOSFET (not a SiC MOSFET), a JFET, a bipolar transistor, a GaN-based switch or an IGBT. It is also possible that an internal gate resistor is arranged. This is also represented by R₄.

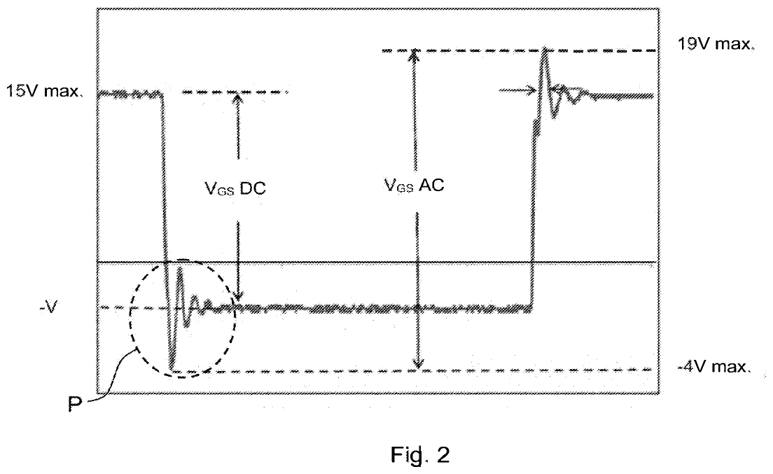

FIG. 2 illustrates the recommended and maximum voltage for carrying out a reliable operation of a SiC MOSFET. It can be seen that a parasitic and unwanted turn-on P occurs. Maintaining a reliable operation of a SiC MOSFET like the one shown in the power electronic module illustrated in FIG. 1, the gate-source voltage V_{G}S is not allowed to fall below −4V. Accordingly, the static gate voltage V₂ has to be above −4V, however, this causes the parasitic turn-on P illustrated in FIG. 2

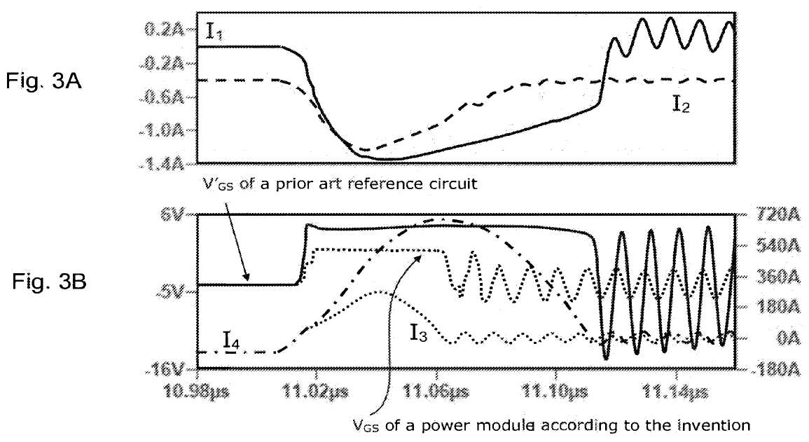

FIG. 3A illustrates a first graph depicting the current I₁ through the terminal inductance (illustrated as L₈ in FIG. 1) as function of time for a power electronic device according to the invention and a second graph depicting the corresponding current I₂ as function of time for a prior art power electronic device. The current I₁ is indicated by a solid line, wherein the current I₂ is indicated by a dashed line.

FIG. 3B illustrates a first graph depicting the gate-source voltage V′_{gs} of a prior art power electronic device (having a reference circuit without Z-diodes) as function of time. FIG. 3B moreover illustrates a second graph depicting the gate-source voltage V_{gs} of a reference circuit of a power electronic device according to the invention (corresponding to the one illustrated in and explained with reference to FIG. 1). It can be seen that the amplitude of the gate-source voltage V′_{gs} of the prior art power electronic device is much larger than the amplitude of the gate-source voltage V_{gs} of a reference circuit of a power electronic device according to the invention.

FIG. 3B illustrates a third graph depicting the reverse recovery current I₄ of a prior art power electronic device (having a reference circuit without Z-diodes) as function of time. FIG. 3B also illustrates a fourth graph depicting the reverse recovery current I₃ of a reference circuit of a power electronic device according to the invention (corresponding to the one illustrated in and explained with reference to FIG. 1). When comparing I₃ and I₄ it can be seen that there is a large parasitic turn-on associated with using a prior art power electronic device (having a reference circuit without Z-diodes).

When applying internal Z-diodes as explained with reference to FIG. 1, these Z-diodes will stabilize the driver voltage of e.g. −7V to −4V. Accordingly, there is a current flow through the terminal and the terminal inductance, which will advantageously affect the inductance.

When the Z-diodes are omitted, the current I₄ during the reverse recovery is raised to a higher level (see the reverse recovery currents I₃ and I₄ with big turn on).

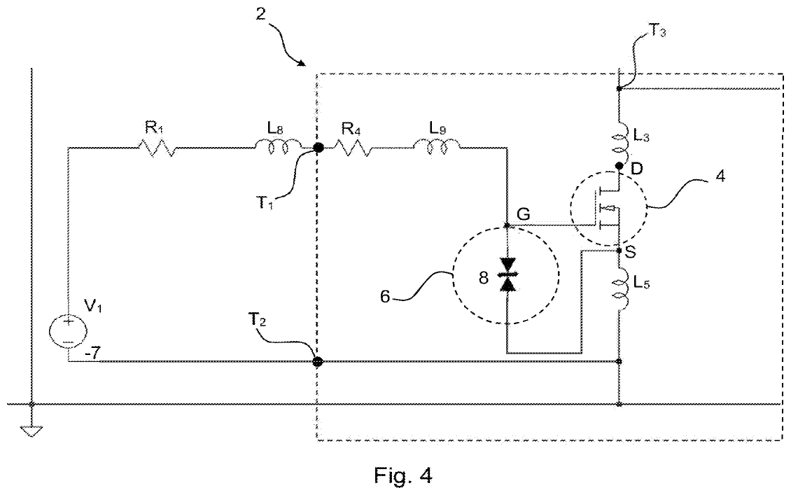

FIG. 4 illustrates a circuit diagram of a second embodiment of a power electronic module 2 according to the invention. The power electronic module 2 comprises a gate-source control unit (also referred to as a gate driver) arranged internally in a power electronic module 2. In a preferred embodiment, the power electronic module 2 comprises a circuit carrier substrate such as a DCB-substrate. A DC voltage source with potentials V₁ and −7V is indicated.

The power electronic module 2 comprises a first terminal T₁ and a second terminal T₂. The power electronic module 2 comprises a semiconductor switch shaped as a SiC MOSFET 4 having a gate terminal G, a source terminal S and a drain terminal D. A TVS diode 8 is arranged between the gate terminal G and the source terminal S of the SiC MOSFET 4. The TVS diode 8 is capable of stabilizing the gate driver voltage.

No additional electrical components other than the TVS diode 8 is arranged between the gate terminal G and the source terminal S of the SiC MOSFET 4. Moreover, the resistance and inductance are indicated by resistors R₁, R₄ and inductors L₃, L₅, L₈, L₉. It is also possible that an internal gate resistor is arranged. This is also represented by R₄.

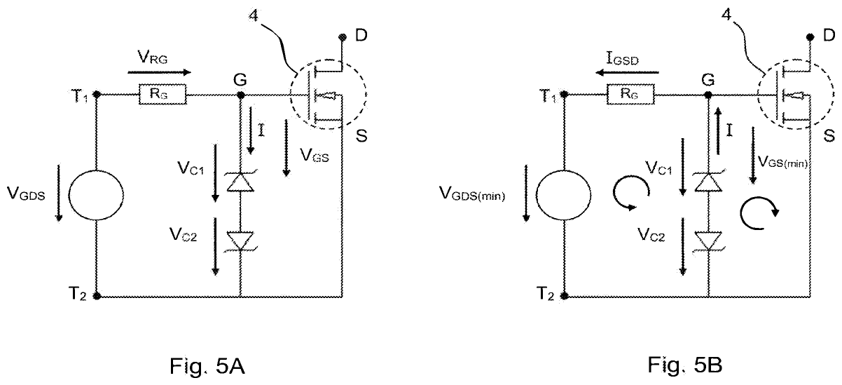

FIG. 5A illustrates a circuit diagram of the gate-source control unit of a power electronic module according to the invention. The circuit diagram is a simplified version of and thus basically corresponds to the diagram shown in FIG. 1. When the gate-source control unit comprise a first and a second Zener diode, the breakdown voltage should be selected in an appropriate manner. In one embodiment gate-source control unit comprise a first avalanche diode having a breakdown voltage in the range of 15-25 V. The second avalanche diode may have a breakdown voltage of 15-25 V.

With reference in FIG. 5A one can find that the following inequality is fulfilled:

(V_{GDS(max)}−V_{RG})>(V_{C1}(I)+V_{C2}(I))>V_{GS(max)} (1)

In normal operation (static) the following is fulfilled:

V_{C1}(I)=V_{GS(max)} (2)

During switching, the gate can be overloaded due to inductance. Accordingly, a non-zero (e.g. 0.5 A) current I is flowing and one can find that:

V_{C1}(I)=V_{GS(max)}−V_{C2}(I) (3)

During short circuit, the above-mentioned equation (3) is valid and the Miller current is significant (e.g. approximately 1 A if V_{GDS(max)} is about 20 V).

FIG. 5B illustrates another view of the same circuit diagram as shown in FIG. 5A. With reference in FIG. 5B one can find derive that

V_{GS(min)}=V_{C1}(I)+V_{C2}(I) (4)

Accordingly, it follows that:

V_{C2}(I)=V_{GS(min)}−V_{C1}(I) (5)

In the static situation we find that:

I=I_{GDS} (6)

It is possible to use compensate for the Miller current (e.g. in the range 1-2 A).

Due to the reverse recovery the VGS is rising very steep. The raise of the VGS and V_{GD} (dV/dt) causes a current through the miller-capacitance. This current has to be drained by the gate drive unit (GDU). The gate resistors and the inductances of the wires will reduce the current derivative (dl/dt) and the capability to drain the current through the Miller capacitance suddenly. If there is a static current (from the Zener diode into the GDU) through the inductance, this current is not needed to be raised. The bias current can compensate the current through the Miller capacitance. The bias current is limited by the power capability of the GDU, the Diodes (Z, TVS or avalanche type) and the gate resistors.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A power electronic module comprising at least one semiconductor switch and a gate-source control unit, wherein the gate-source control unit comprise an asymmetric transient voltage suppressor (TVS) diode or two Zener diodes or one or more avalanche diodes arranged between the gate terminal and the source terminal of the semiconductor switch.

2. The power electronic module according to claim 1, wherein the semiconductor switch is a Power Metal-Oxide-Semiconductor Field-Effect Transistor (MOSFET).

3. The power electronic module according to claim 1, wherein the semiconductor switch is a junction gate field-effect transistor (JFET).

4. The power electronic module according to claim 1, wherein the semiconductor switch is a bipolar transistor.

5. The power electronic module according to claim 1, wherein the semiconductor switch is a SiC-based semiconductor switch.

6. The power electronic module according to claim 1, wherein the semiconductor switch is a Gallium nitride (GaN)-based switch.

7. The power electronic module according to claim 1, wherein the semiconductor switch is an Insulated Gate Bipolar Transistor (IGBT).

8. The power electronic module according to claim 2, wherein the semiconductor switch is a N-Channel Enhancement Mode MOSFET.

9. The power electronic module according to claim 2, wherein the semiconductor switch is a silicon carbide (SiC) MOSFET.

10. The power electronic module according to claim 1, wherein the power electronic module comprises:
a first terminal electrically connected to the gate terminal;
a second terminal electrically connected to the source terminal; and
a third terminal electrically connected to the drain terminal of the semiconductor switch,
wherein no Zener diode is arranged between the source terminal and the drain terminal.

11. The power electronic module according to claim 1, wherein the gate-source control unit comprise a first avalanche diode that has a breakdown voltage in the range of 5-35 V and a second avalanche diode that has a breakdown voltage of 5-35 V.

12. The power electronic module according to claim 2, wherein the semiconductor switch is MOSFET that has a maximum dynamic gate-source voltage range of −8V to 19V.

13. The power electronic module according to claim 1, wherein the power electronic module is configured to drive the asymmetric TVS diode or the two Zener diodes or the one or more avalanche diodes with a static current.

14. The power electronic module according to claim 1, wherein the gate-source control unit is arranged internally in the power electronic module and that the power electronic module comprises a circuit carrier substrate.

15. The power electronic module according to claim 1, wherein no additional electrical components other than the TVS diode or two Zener diodes or the one or more avalanche diodes are arranged between the gate terminal and the source terminal of the semiconductor switch.

16. The power electronic module according to claim 1, wherein the gate-source control unit is mounted on the same substrate as the semiconductor switch.

17. The power electronic module according to claim 1, wherein the gate-source control unit is mounted a different substrate to the substrate on which the semiconductor switch is mounted.

18. The power electronic module according to claim 8, the semiconductor switch is a silicon carbide (SiC) MOSFET.
